(19) United States
(12) Patent Application Publication
(10) Pub. No.: US 2002/0197858 A1
(43) Pub. Date: Dec. 26, 2002

(54) Method for fabricating semiconductor devices

(76) Inventors: Chieh-Ju Chang, Yunlin Hsien (TW); Tsai-Sen Lin, Taichung (TW); Chon-Shin Jou, Hsinchu (TW); Lung-Yu Yen, Tainan (TW)

Correspondence Address: Chien-Wei (Chris) Chuo, Esq, Openheimer Wolff & Donnelly LLP, 840 New Port Center Dr, Suite 700, New Port Beach, CA, 92606, US

(21) Appl. No.: 09/990,214

(22) Filed: Nov. 21, 2001

(30) Foreign Application Priority Data
Jun. 26, 2001 (TW) 90115410

(51) Int. Cl. H01L 21/44

(52) U.S. Cl. 438/655; 438/664; 438/682

(57) ABSTRACT

The present invention provides a method for fabricating semiconductor devices, which includes the following steps. First, a silicide layer is formed on a substrate. Then, the silicide layer is defined, and an oxide layer is formed uniformly on the substrate and the silicide layer. Next, the oxide layer is etched to form a sidewall oxide layer by dry etching process, and the remaining oxide layer on the substrate is removed by wet etching. Next, inactive gas is added to the surface of the silicide layer to perform an anneal process. Finally, a mask oxide layer is formed on the silicide layer.

### BACKGROUND OF THE INVENTION

1. Field of the Invention

The present invention relates in general to a method for fabricating semiconductor devices. In particular, the present invention relates to a method for fabricating semiconductor devices while avoiding the formation of pinholes on the surface of the silicide layer after chemical vapor deposition (CVD) and physical vapor deposition (PVD).

2. Description of the Related Art

In conventional semiconductor process, the sidewall oxide layer on a substrate is removed by dry etching. However, the surface of the substrate tends to be damaged with overetching. Therefore, when removing the sidewall oxide layer on a substrate, dry etching and wet etching are employed to avoid damaging the substrate.

FIG. 1A to FIG. 1F are sectional views of the semiconductor devices of the conventional semiconductor process.

In FIG. 1A, a polysilicon layer 12 is formed on a substrate 11. Next, silicide layer 13 is formed on polysilicon layer 12 by PVD. Then, referring to FIG. 1B, silicide layer 13 and polysilicon layer 12 are defined by photolithographic techniques and etching. Next, referring to FIG. 1C, oxide layer 14 is uniformly formed on the substrate 11 and silicide layer 13. The oxide layer can be silicon dioxide (SiO₂). Referring to FIG. 1D, oxide layer 14 is dry etched to form sidewall oxide layer 141. In addition, partial oxide layer 142 is left on the substrate 11 by controlling the timing of dry etching to avoid damaging substrate 11 by overetching. Next, referring to FIG. 1E, the remaining oxide layer 142 on the substrate 11 is removed by wet etching process. Here, hydrofluoric acid (HF) is used as etching liquid, because HF has a lower etching rate to substrate 11 than oxide layer 142. Therefore, the oxide layer 142 can be removed without damaging substrate 11. Finally, a mask oxide layer 15 is formed on substrate 11 and silicide layer 13 and between polysilicon layer 12 and silicide layer 13.

While the method described removes the oxide layer 142 remaining on substrate 11 by dry etching and wet etching without damaging the surface of the substrate by overetching, the surface of silicide layer 13 will experience the formation of pinholes 131 (referring to FIG. 1E) by HF eroding silicide layer 13 during wet etching, because the erosion of HF will generate the unconnected Si bonds. When mask oxidation is performed, oxygen penetrates the pinholes and combines with the bonds, forming silicon dioxide and the roughness surface. This roughening of the surface of silicide layer 13 both influences the structure of mask oxide layer and causes a raising of the silicide layer itself (label 151).

### SUMMARY OF THE INVENTION

The object of the present invention is to provide a method for fabricating semiconductor devices, the method performing the anneal process by adding inactive gas to the surface of the silicide layer to repair the pinholes generated by HF. Thus, the surfaces of the silicide layer and mask oxide layer become smooth.

To achieve the above-mentioned object, the present invention provides a method for fabricating semiconductor devices, which comprises the following steps. First, a silicide layer is formed on a substrate. Then, the silicide layer is defined, and an oxide layer is formed uniformly on the substrate and the silicide layer. Next, the oxide layer is etched to form a sidewall oxide layer by dry etching, and the remaining oxide layer on the substrate is removed by wet etching. Next, inactive gas is added to the surface of the silicide layer to perform anneal process. Finally, a mask oxide layer is formed on the silicide layer.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIG. 1A to FIG. 1F are sectional views of the semiconductor devices of the conventional semiconductor process.

FIG. 2A to FIG. 2G are sectional views of the semiconductor devices of the semiconductor process according to the embodiment of the present invention.

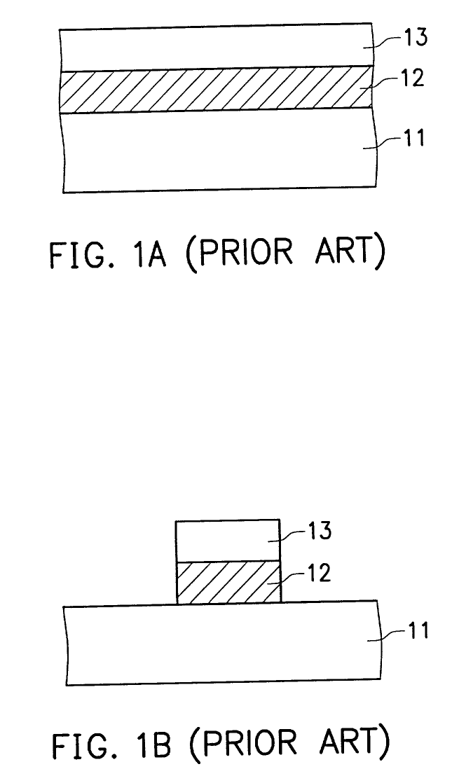

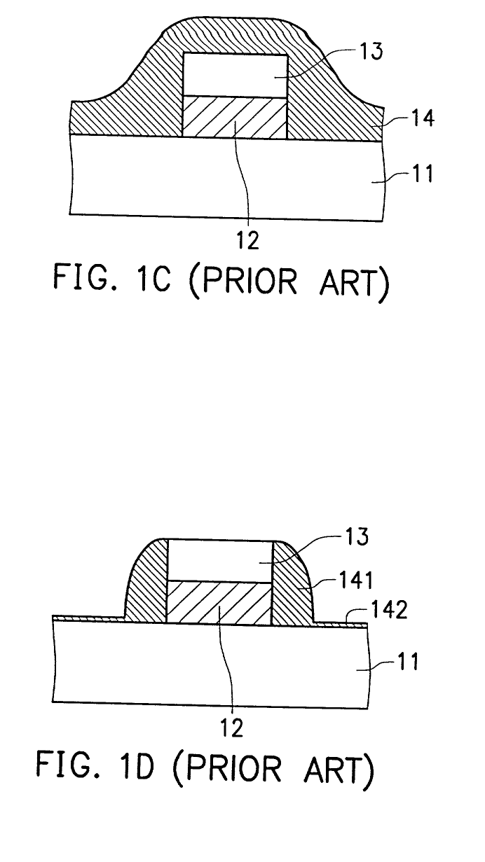

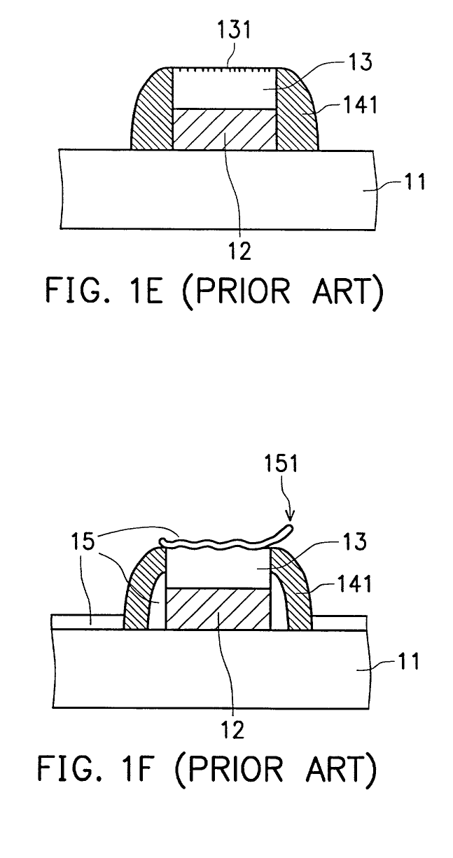

### DETAILED DESCRIPTION OF THE PREFERRED EMBODIMENT

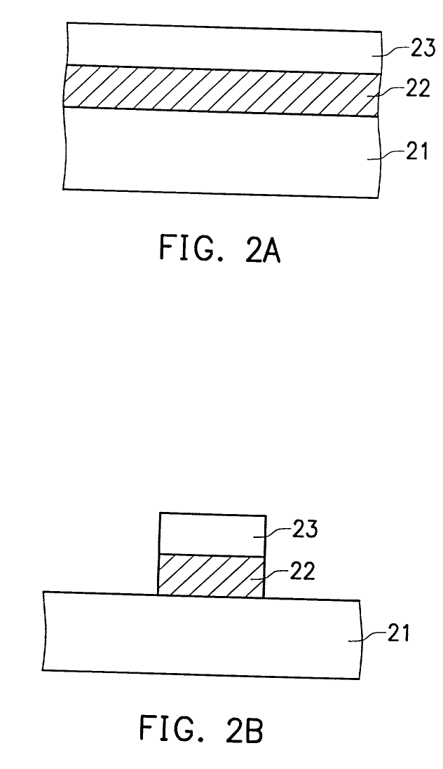

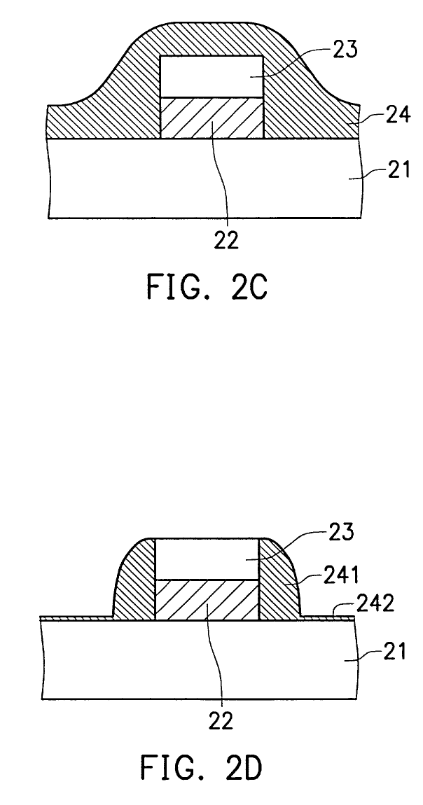

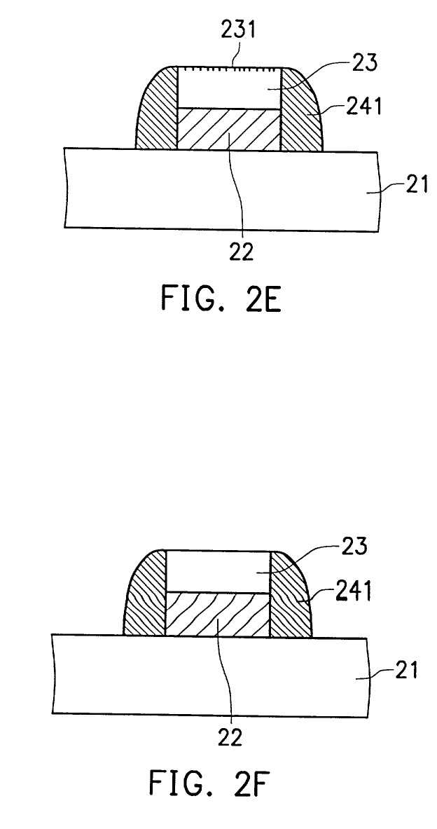

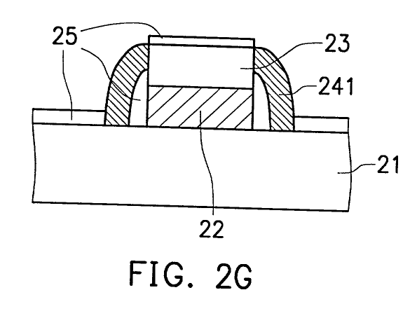

FIG. 2A to FIG. 2G are section views of the semiconductor devices of the semiconductor process according to the embodiment of the present invention.

In FIG. 2A, a polysilicon layer 22 is formed on a substrate 21. Next, silicide layer 23 is formed on polysilicon layer 22 by PVD. In the present embodiment, the silicide layer 23 is tungsten silicide (WSix).

Then, referring to FIG. 2B, silicide layer 23 and polysilicon layer 22 are defined by photolithographic techniques and etching. Next, referring to FIG. 2C, oxide layer 24 is formed uniformly on the substrate 21 and silicide layer 23. The oxide layer can be silicon dioxide (SiO₂). Referring to FIG. 2D, oxide layer 24 is dry etched to form sidewall oxide layer 241. In addition, partial oxide layer 242 is left on the substrate 21 by controlling the timing of dry etching to avoid substrate 21 damaged with overetching. Next, referring to FIG. 2E, the remaining oxide layer 242 on the substrate 21 is removed by wet etching. Here, hydrofluoric acid (HF) is used as etching liquid, because HF has a lower etching rate to substrate 21 than oxide layer 242. Therefore, the oxide layer 242 can be removed without damaging substrate 21.

As mentioned above, the surface of silicide layer 23 will experience the formation of pinholes 231 (referring to FIG. 2E) by HF eroding silicide layer 23 during wet etching. Therefore, the present invention performs an anneal process by adding inactive gas to the surface of the silicide layer to repair pinholes 231 on silicide layer 23. Here, the temperature of the anneal process is about 20 to 800, and the performing time of the anneal process is about 25 to 35 minutes. In addition, the inactive gas is nitrogen gas or inert gas. But with the consideration of cost, nitrogen gas is empolyed in the present invention. Resultingly, referring to FIG. 2F, the surface of silicide layer 23 doesn't experience the formation of pinholes.

Finally, referring to FIG. 2G, a mask oxide layer 25 is formed on substrate 21 and silicide layer 23 and between polysilicon layer 22 and silicide layer 23.

As shown in FIG. 2F, the surface of silicide layer 23 is annealed to eliminate pinholes. Therefore, when mask oxidation is performed, oxygen will not penetrate the surface of silicide layer 23, so the surfaces of silicide layer 23 and mask oxide layer 25 are smooth.

Accordingly, the present invention provides a method for fabricating semiconductor devices, the method performs anneal process by adding inactive gas to the surface of the silicide layer to repair the pinholes generated by HF on the surface of the silicide layer after dry etching and wet etching. Therefore, the surface of the silicide layer and mask oxide layer become smooth. Moreover, the continued process will be more smooth going.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A method for fabricating semiconductor devices, comprising the following steps:
providing a substrate;
forming a silicide layer on the substrate;
defining the silicide layer;
uniformly forming an oxide layer on the substrate and the silicide layer;
etching the oxide layer to form a sidewall oxide layer by dry etching;
removing the remaining oxide layer on the substrate by wet etching;
adding an inactive gas to the surface of the silicide layer to perform an anneal process; and
forming a mask oxide layer on the silicide layer.

2. The method as claimed in claim 1, wherein the temperature of the anneal process is about 20 to 800.

3. The method as claimed in claim 1, wherein the performance time of the anneal process is about 25 to 35 minutes.

4. The method as claimed in claim 1, further comprising a step: forming a polysilicon layer on the substrate before forming the silicide layer.

5. The method as claimed in claim 1, wherein the silicide layer is formed by physical vapor deposition.

6. The method as claimed in claim 5, wherein the silicide layer is Tungsten silicide (WSix).

7. The method as claimed in claim 1, wherein the oxide layer is formed by chemical vapor deposition.

8. The method as claimed in claim 1, wherein the inactive gas is nitrogen gas.

9. The method as claimed in claim 1, wherein the inactive gas is inert gas.
